(19) United States
(12) Patent Application Publication
(10) Pub. No.: US 2026/0099099 A1
(43) Pub. Date: Apr. 9, 2026

(54) METHOD AND SYSTEM FOR DIE TO WAFER BONDING

(71) Applicant: TOKYO ELECTRON LIMITED, Tokyo (JP)

(72) Inventors: Anthony SCHEPIS, Averill Park, NY (US); David POWER, Albany, NY (US); David CONKLIN, Saratoga Springs, NY (US)

(73) Assignee: TOKYO ELECTRON LIMITED, Tokyo (JP)

(21) Appl. No.: 18/906,216

(22) Filed: Oct. 4, 2024

(51) Int. Cl. G03F 7/00; H01L 21/66

(52) U.S. Cl. CPC G03F 7/705; G03F 7/70625; H10P 74/203; H10P 74/238

(57) ABSTRACT

This disclosure provides methods and systems of processing a semiconductor wafer. One method includes obtaining wafer characterization metrology information of a wafer, the wafer including a plurality of dies, and generating a plurality of predicted die shapes based on the wafer characterization metrology information being input into a computing model. Each of the plurality of predicated die shapes corresponds to one of the plurality of dies of the wafer. The method further includes processing the wafer to obtain the plurality of dies and processing the plurality of dies based on the plurality of predicated die shapes.

### TECHNICAL FIELD

This disclosure relates generally to semiconductor packaging, and particularly to techniques for die to wafer bonding.

### BACKGROUND

A wafer that integrates hundreds of layers may go through multiple processing steps, such as heating in furnace, chemical vapor deposition, lithography patterning, and the like. These multiple processing steps can introduce a non-uniform wafer stress to the wafer.

With the advent of three dimensional (3D) packaging, the semiconductor industry is entering a critical juncture where the traditional die-to-wafer bonding based alignment corrections are not able to account for the non-linear physical effects induced via the multiple processing steps. That is, the non-uniform wafer stress introduced to the wafer prior to the die-to-wafer bonding operation can impart specific localized shape distortions for an individual chiplet that is diced from the wafer. The shape distortions can cause alignment failures and can compromise the critical bonding metrics, resulting in significant yield loss in the advanced packaging process. Accordingly, it is desired to characterize the die level shape of the individual die so that advance process countermeasure technologies can be enabled to reduce the yield loss.

### SUMMARY

This disclosure provides a method of processing a semiconductor wafer. The method includes obtaining wafer characterization metrology information of a wafer, the wafer including a plurality of dies, and generating a plurality of predicted die shapes based on the wafer characterization metrology information being input into a computing model. Each of the plurality of predicated die shapes corresponds to one of the plurality of dies of the wafer. The method further includes processing the wafer to obtain the plurality of dies and processing the plurality of dies based on the plurality of predicated die shapes.

Aspects of the disclosure provide a semiconductor processing system. The semiconductor processing system includes processing circuitry configured to obtain wafer characterization metrology information of a wafer. The wafer includes a plurality of dies. The processing circuitry is further configured to generate a plurality of predicted die shapes based on the wafer characterization metrology information being input into a computing model. Each of the plurality of predicated die shapes corresponding to one of the plurality of dies of the wafer. The processing circuitry is configured to process the wafer to obtain the plurality of dies, and process the plurality of dies based on the plurality of predicated die shapes.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A and 1B show the low order global distortion and high order local distortion of a height variation of a semiconductor wafer according to embodiments of the disclosure.

FIG. 2 shows an example of a die-level distortion according to embodiments of the disclosure.

FIG. 3 shows an example of a hybrid virtual metrology system according to embodiments of the disclosure.

FIG. 4 illustrates a process according to an embodiment of the disclosure.

### DETAILED DESCRIPTION

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

A functional semiconductor wafer can be formed through an integration of multiple (e.g., over 70) individual layers that ultimately culminates in the functional device. During the integration, each individual layer may require multiple process steps that include, but are not limited to, thin film deposition, lithography, and etches to form desired structures of the semiconductor wafer. Through these process steps, various non-uniform wafer stresses can be induced. For example, one of the non-uniform wafer stresses can be resulted from the patterning of thin films and can be amplified via multiple temperature cycling processes. Thus, the non-uniform wafer stresses can fundamentally distort wafer grids of the semiconductor wafer.

According to embodiments of the disclosure, the distortions of the wafer grids of the semiconductor wafer can include a low order global distortion and a high order local distortion.

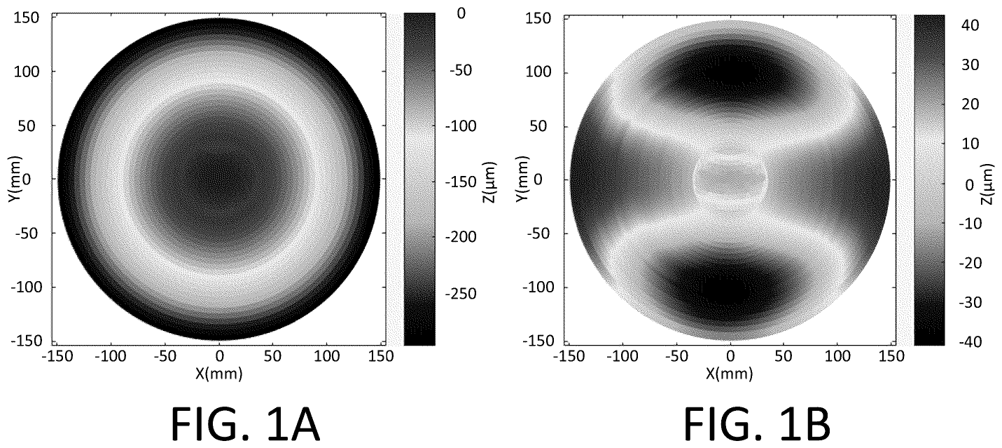

FIGS. 1A and 1B show the low order global distortion and high order local distortion of a height variation of a semiconductor wafer according to embodiments of the disclosure. In the FIGS. 1A and 1B examples, the diameter of the semiconductor wafer is 300 mm. As shown in FIG. 1A, the low order global distortion of the height variation (along z-axis) of the semiconductor wafer ranges from −250 μm to 0 μm. As shown in FIG. 1B, the high order local distortion of the heigh variation (along z-axis) of the semiconductor wafer ranges from −40 μm to 40 μm. It is noted that the high order local distortion may exist as a stand-alone distortion or may be embedded in the low order global distortion. A combination of the low order global distortion and high order local distortion can form a total wafer stress of the semiconductor wafer. Each of the low order global distortion and the higher order local distortion can be obtained by using a semiconductor metrology equipment.

According to embodiments of the disclosure, a semiconductor wafer can be diced into multiple individual dies (or chiplets). For example, semiconductor devices can be formed on a bulk substrate of the semiconductor wafer. After the semiconductor devices have been fully formed on the bulk substrate, the semiconductor devices can be released from the bulk substrate to generate the individual dies through a packaging process for example.

Each of the individual dies can be bonded to a separate wafer substrate, and this bonding process can be referred to as a die-to-wafer bonding process.

The non-uniform stresses, such as the low and/or high order distortions, can complicate the die-to-wafer bonding process and negatively impact the bonding yield of the die-to-wafer bonding process. For example, a semiconductor wafer can include hundreds of individual dies formed on a bulk substrate of the semiconductor wafer. The non-uniform stresses generated at the wafer level can be redistributed amongst the hundreds of individual dies in a location specific manor once the individual dies have been released from the bulk substrate of the semiconductor wafer. That is, the stress profile of the whole wafer can be redistributed to each individual die. The redistributed stress profile depends on where the individual die locates on the semiconductor wafer.

The stress redistributed onto an individual die can be referred to as a die-level distortion. A magnitude of the die-level distortion can be a several order of a magnitude of the wafer-level stress.

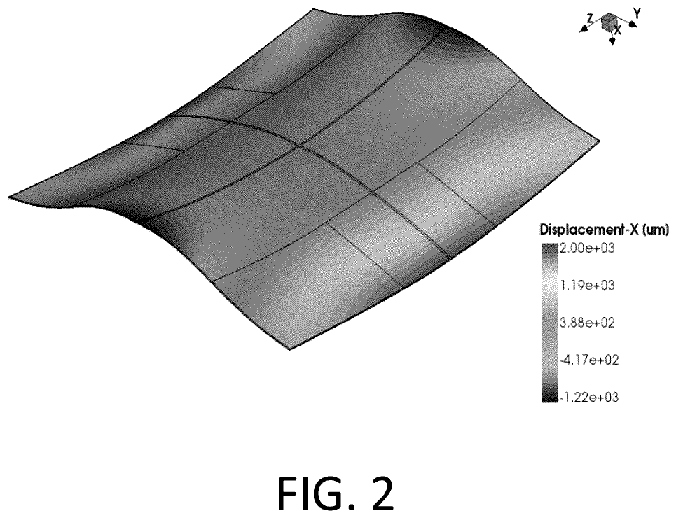

FIG. 2 shows an example of a die-level distortion according to embodiments of the disclosure. As shown in FIG. 2, a displacement of a height (along X-axis) of a die can range from −1.22×103 μm to 2.00×103 μm. Compared to the FIGS. 1A and 1B examples, the range of the die-level distortion shown in the FIG. 2 example is tens of the range of the wafer-level distortion.

The distortions can result in residual overlay errors that are uncorrected during the packaging process. If the residual overlay errors are large enough in magnitude, they can cause critical failures in electrical continuity and thus decrease the device yield. Accordingly, it is important to obtain the distortion information during the die-to-wafer bonding process, so that certain countermeasures can be executed using advance process technologies to preserve the device yield.

The distortion information of an individual die can be obtained by measuring a die shape of the individual die. However, measuring the die shape may need an additional processing to the individual die, reducing the surface integrity of the individual die. For example, particles or contaminants may land on the individual die undergoing the measurement. The contaminants are detrimental to the bonding process and can further compromise the device yield. Furthermore, measuring hundreds of individual dies formed from the singulation of wafers requires a high throughput of the die processing.

This disclosure provides methods of obtaining stress (or distortion) information of an individual die. The methods can significantly reduce the yield cost and throughput requirement and improve the device yield. In the methods, a hybrid virtual metrology system can be used to characterize the die shape of the individual die. The hybrid virtual metrology system can include a semiconductor metrology equipment that is used to measure the wafer-level stress of a whole wafer that includes the individual die. The hybrid virtual metrology system can further include a computing device that is used to simulate the die-level stress profile based on the measured wafer-level stress of the wafer and the die location of the individual die.

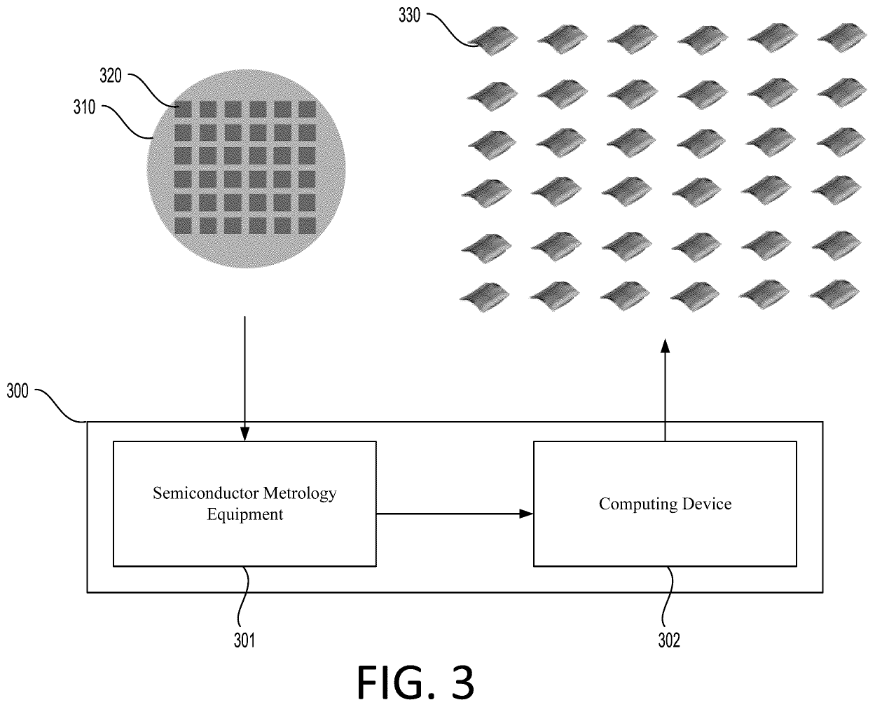

FIG. 3 shows an example of a hybrid virtual metrology system 300 according to embodiments of the disclosure. The hybrid virtual metrology system 300 includes a semiconductor metrology equipment 301 and a computing device 302.

The semiconductor metrology equipment 301 can obtain wafer characterization metrology information of a wafer 302 that includes a plurality of dies 320. For example, the semiconductor metrology equipment 301 can perform a full wafer shape measurement and/or a wafer level overlay metrology measurement onto the wafer 310 to obtain the wafer characterization metrology information of the wafer 310.

In an embodiment, from the full wafer shape measurement and/or the wafer level overlay metrology measurement, the hybrid virtual metrology system 300 can obtain various distortion information of the wafer 310. For example, the hybrid virtual metrology system 300 can obtain at least one of or a combination of the low order global distortion, the high order local distortion, or the in plane distortion of the wafer 310.

In an embodiment, from the full wafer shape measurement and/or the wafer level overlay metrology measurement, the hybrid virtual metrology system 300 can obtain integrated wafer stack information of the wafer 310. For example, the hybrid virtual metrology system 300 can obtain at least one of material information, layer information, or pattern information of the wafer 310. The hybrid virtual metrology system can also obtain location information of each die 320 included in the wafer 310.

According to aspects of the disclosure, the obtained wafer characterization metrology information can be input into a computing model that runs on the computing device 302 of the hybrid virtual metrology system 300. Based on the wafer characterization metrology information of the wafer 310, the computing model can output a predicted die shape 330 for each die 320 included in the wafer 310.

In an embodiment, the computing model can be a physics based model (e.g., finite element model) or a machine learning model (e.g., a convolutional neural network model), or a combination of the physics based model and the machine learning model.

In an embodiment, the predicated die shapes 330 of the dies 320 included in the wafer 310 can be feed forward to a process controller that controls a processing equipment to further process the dies. For example, the processing equipment can be a bonding system, and the process controller can calculate a bonding yield for the dies 320 based on the predicted die shapes 330, sort the dies 320 based on the bonding yield, and control the bonding system to bond at least a subset of the dies 320 based on the sorting of the dies 320. To determine the subset of the dies 320, the process controller can compare the bonding yield of the subset of the dies 320 with a bonding yield threshold. If the bonding yield of the subset of the dies 320 is greater than the bonding yield threshold, the subset of the dies can be selected for the die-to-wafer bonding process.

In an embodiment, the computing model can be updated based on measuring a subset of the die shapes 330. For example, the die shapes 330 of a subset of the dies 320 can be measured using a semiconductor metrology system (e.g., the semiconductor metrology equipment 310), and the measured die shapes can be feedback to the computing model, so that the computing model can be updated based on the measured die shapes of the subset of the dies 320, and the accuracy of the computing model can be improved.

By using the hybrid virtual metrology system 300 instead of measuring each die, the defects from measuring every die can be reduced, the bonding yield can be improved, and the throughput can be improved.

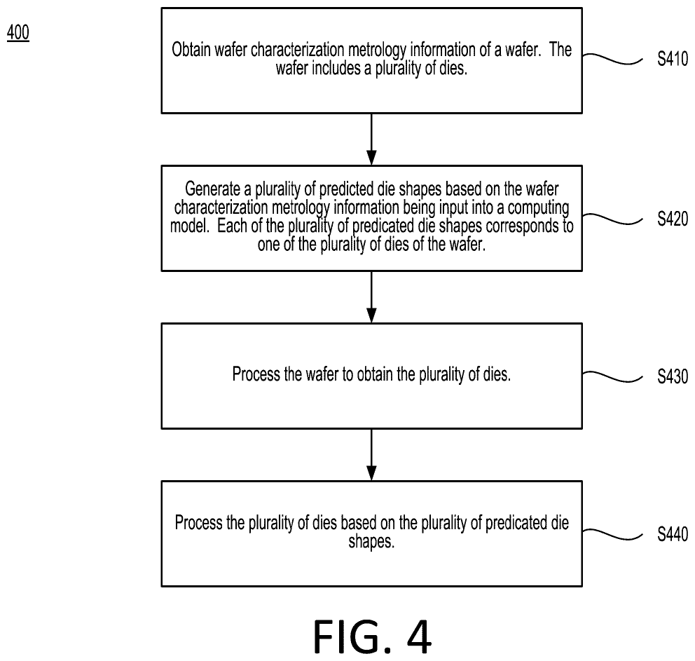

FIG. 4 illustrates a process 400 according to an embodiment of the disclosure. The process 400 can be implemented by a semiconductor processing system (e.g., the hybrid virtual metrology system 300). The process 400 can be implemented as instructions stored in a non-transitory computer-readable medium. When executed by for example the semiconductor processing system, the instructions can cause the semiconductor processing system to perform the process 400. The process 400 may start at step S410.

At step S410, the process 400 can obtain wafer characterization metrology information of a wafer. The wafer includes a plurality of dies. Then, the process 400 can proceed to step S420.

At step S420, the process 400 can generate a plurality of predicted die shapes based on the wafer characterization metrology information being input into a computing model. Each of the plurality of predicated die shapes corresponds to one of the plurality of dies of the wafer. Then, the process 400 can proceed to step S430.

At step S430, the process 400 can process the wafer to obtain the plurality of dies. Then, the process 400 can proceed to step S440.

At step S440, the process 400 can process the plurality of dies based on the plurality of predicated die shapes.

In an embodiment, the wafer characterization metrology information of the wafer includes at least one of full wafer shape information or wafer level overlay metrology information of the wafer.

In an embodiment, the wafer characterization metrology information of the wafer includes at least one of or a combination of global distortion information, local distortion information, or in-plane distortion information of the wafer.

In an embodiment, the wafer characterization metrology information of the wafer includes at least one of material information, layer information, or pattern information of the wafer.

In an embodiment, the wafer characterization metrology information of the wafer includes location information of each of the plurality of dies.

In an embodiment, the computing model includes one of or a combination of a physics based model and a machine learning based model.

In an embodiment, the physics based model includes a finite element model.

In an embodiment, the process 400 can feed forward the plurality of predicted die shapes to a process controller.

In an embodiment, the process controller controls a bonding system, and the process 400 can calculate a bonding yield for the plurality of dies based on the plurality of predicted die shapes, sort the plurality of dies based on the bonding yield, and control the bonding system to bond a subset of the plurality of dies based on the sorting of the plurality of dies.

In an embodiment, the process 400 can measure die shapes of a subset of the plurality of dies using a semiconductor metrology system, and update the computing model based on the measured die shapes of the subset of the plurality of dies.

Aspects of the disclosure provide a semiconductor processing system. The semiconductor processing system includes processing circuitry configured to obtain wafer characterization metrology information of a wafer. The wafer includes a plurality of dies. The processing circuitry is further configured to generate a plurality of predicted die shapes based on the wafer characterization metrology information being input into a computing model. Each of the plurality of predicated die shapes corresponding to one of the plurality of dies of the wafer. The processing circuitry is configured to process the wafer to obtain the plurality of dies, and process the plurality of dies based on the plurality of predicated die shapes.

In an embodiment, the wafer characterization metrology information of the wafer includes at least one of full wafer shape information or wafer level overlay metrology information of the wafer.

In an embodiment, the wafer characterization metrology information of the wafer includes at least one of or a combination of global distortion information, local distortion information, or in-plane distortion information of the wafer.

In an embodiment, the wafer characterization metrology information of the wafer includes at least one of material information, layer information, or pattern information of the wafer.

In an embodiment, the wafer characterization metrology information of the wafer includes location information of each of the plurality of dies.

In an embodiment, the computing model includes one of or a combination of a physics based model and a machine learning based model.

In an embodiment, the physics based model includes a finite element model.

In an embodiment, the processing circuitry is configured to feed forward the plurality of predicted die shapes to a process controller.

In an embodiment, the process controller controls a bonding system, and the processing circuitry is configured to calculate a bonding yield for the plurality of dies based on the plurality of predicted die shapes, sort the plurality of dies based on the bonding yield, and control the bonding system to bond a subset of the plurality of dies based on the sorting of the plurality of dies.

In an embodiment, the processing circuitry is configured to measure die shapes of a subset of the plurality of dies using a semiconductor metrology system, and update the computing model based on the measured die shapes of the subset of the plurality of dies.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

1. A method of processing a semiconductor wafer, the method comprising:
obtaining wafer characterization metrology information of a wafer, the wafer including a plurality of dies;
generating a plurality of predicted die shapes based on the wafer characterization metrology information being input into a computing model, each of the plurality of predicated die shapes corresponding to one of the plurality of dies of the wafer;
processing the wafer to obtain the plurality of dies; and
processing the plurality of dies based on the plurality of predicated die shapes.

2. The method of claim 1, wherein the wafer characterization metrology information of the wafer includes at least one of full wafer shape information or wafer level overlay metrology information of the wafer.

3. The method of claim 1, wherein the wafer characterization metrology information of the wafer includes at least one of or a combination of global distortion information, local distortion information, or in-plane distortion information of the wafer.

4. The method of claim 1, wherein the wafer characterization metrology information of the wafer includes at least one of material information, layer information, or pattern information of the wafer.

5. The method of claim 1, wherein the wafer characterization metrology information of the wafer includes location information of each of the plurality of dies.

6. The method of claim 1, wherein the computing model includes one of or a combination of a physics based model and a machine learning based model.

7. The method of claim 1, wherein the physics based model includes a finite element model.

8. The method of claim 1, wherein the processing the plurality of dies includes:
feeding forward the plurality of predicted die shapes to a process controller.

9. The method of claim 8, wherein the process controller controls a bonding system, and the processing the plurality of dies further includes:
calculating a bonding yield for the plurality of dies based on the plurality of predicted die shapes;
sorting the plurality of dies based on the bonding yield; and
controlling the bonding system to bond a subset of the plurality of dies based on the sorting of the plurality of dies.

10. The method of claim 1, further comprising:
measuring die shapes of a subset of the plurality of dies using a semiconductor metrology system; and
updating the computing model based on the measured die shapes of the subset of the plurality of dies.

11. A semiconductor processing system, comprising:
processing circuitry configured to
obtain wafer characterization metrology information of a wafer, the wafer including a plurality of dies,
generate a plurality of predicted die shapes based on the wafer characterization metrology information being input into a computing model, each of the plurality of predicated die shapes corresponding to one of the plurality of dies of the wafer,
process the wafer to obtain the plurality of dies, and
process the plurality of dies based on the plurality of predicated die shapes.

12. The semiconductor processing system of claim 11, wherein the wafer characterization metrology information of the wafer includes at least one of full wafer shape information or wafer level overlay metrology information of the wafer.

13. The semiconductor processing system of claim 11, wherein the wafer characterization metrology information of the wafer includes at least one of or a combination of global distortion information, local distortion information, or in-plane distortion information of the wafer.

14. The semiconductor processing system of claim 11, wherein the wafer characterization metrology information of the wafer includes at least one of material information, layer information, or pattern information of the wafer.

15. The semiconductor processing system of claim 11, wherein the wafer characterization metrology information of the wafer includes location information of each of the plurality of dies.

16. The semiconductor processing system of claim 11, wherein the computing model includes one of or a combination of a physics based model and a machine learning based model.

17. The semiconductor processing system of claim 11, wherein the physics based model includes a finite element model.

18. The semiconductor processing system of claim 11, wherein the processing circuitry is configured to feed forward the plurality of predicted die shapes to a process controller.

19. The semiconductor processing system of claim 18, wherein the process controller controls a bonding system, and the processing circuitry is configured to:
calculate a bonding yield for the plurality of dies based on the plurality of predicted die shapes;
sort the plurality of dies based on the bonding yield; and
control the bonding system to bond a subset of the plurality of dies based on the sorting of the plurality of dies.

20. The semiconductor processing system of claim 11, wherein the processing circuitry is configured to:
measure die shapes of a subset of the plurality of dies using a semiconductor metrology system; and
update the computing model based on the measured die shapes of the subset of the plurality of dies.
